(19) United States
(12) Patent Application Publication
(10) Pub. No.: US 2026/0067754 A1
(43) Pub. Date: Mar. 5, 2026

(54) AMBIENT POWER WIFI DOWNLINK PREAMBLE SYNC DESIGN

(71) Applicant: NXP USA, Inc., AUSTIN, TX (US)

(72) Inventors: Rui Cao, Sunnyvale, CA (US); Sergey Timofeev, Mountain View, CA (US); Hongyuan Zhang, Fremont, CA (US); Franz Amtmann, Graz (AT); Xilin Cheng, Menlo Park, CA (US); Zheng Guo, Newark, CA (US)

(21) Appl. No.: 19/319,610

(22) Filed: Sep. 4, 2025

Related U.S. Application Data
(60) Provisional application No. 63/690,727, filed on Sep. 4, 2024.
(60) Provisional application No. 63/712,009, filed on Oct. 25, 2024.
(60) Provisional application No. 63/736,494, filed on Dec. 19, 2024.
(60) Provisional application No. 63/839,829, filed on Jul. 7, 2025.
(60) Provisional application No. 63/849,318, filed on Jul. 23, 2025.

(51) Int. Cl. H04W 28/20; H02J 50/00; H03M 5/12; H04L 5/00; H04L 27/04; H04L 27/06

(52) U.S. Cl. CPC H04W 28/20; H03M 5/12; H04L 5/0048; H04L 27/04; H04L 27/06; H02J 50/001

(57) ABSTRACT

Methods and apparatus are provided for communicating with an ambient power (AMP) tag device by an AMP-compliant WiFi device. A method includes generating a physical layer protocol data unit (PPDU) that includes a preamble that is compliant with an Institute of Electrical and Electronics Engineers (IEEE) 802.11 standard. The PPDU further includes an AMP preamble including a synchronization (SYNC) field and an AMP data frame carrying downlink (DL) data. In this method, the SYNC field of the AMP preamble includes an On-Off keying (OOK) modulated SYNC sequence, the SYNC sequence including an indication of a first data rate or a second data rate for the DL data, or an indication of a first operating frequency band or a second operating frequency band. The method further includes transmitting, by the WiFi device, the PPDU for reception by the AMP tag device.

### CROSS REFERENCE TO RELATED APPLICATIONS

The present U.S. Utility patent application claims priority pursuant to 35 U.S.C. § 119 (c) to U.S. Provisional Application No. 63/690,727, entitled “AMBIENT POWER WIFI DOWNLINK WAVEFORM AND PPDU DESIGN”, filed Sep. 4, 2024, U.S. Provisional Application No. 63/712,009, entitled “AMBIENT POWER WIFI DOWNLINK PREAMBLE DESIGN”, filed Oct. 25, 2024, U.S. Provisional Application No. 63/736,494, entitled “AMBIENT POWER WIFI DOWNLINK PREAMBLE SYNC DESIGN”, filed Dec. 19, 2024, U.S. Provisional Application No. 63/839,829, entitled “AMBIENT POWER WIFI DOWNLINK PREAMBLE SYNC DESIGN”, filed Jul. 7, 2025, and U.S. Provisional Application No. 63/849,318, entitled “AMBIENT POWER WIFI DOWNLINK PREAMBLE SYNC DESIGN”, filed Jul. 23, 2025, the contents of each of which is hereby incorporated herein by reference in its entirety and made part of the present U.S. Utility patent application for all purposes.

### TECHNICAL FIELD

This disclosure relates generally to data communications, and more particularly, to methods and apparatus for ambient power downlink communications based on Institute of Electrical and Electronics Engineers (IEEE) 802.11 bp.

### BACKGROUND

Existing Ultra-High Frequency Radio Frequency Identification (UHF RFID) standards, such as EPC Gen2, provide an air-interface protocol that defines how passive RFID tags and readers communicate through battery-less backscattering in the UHF band (approximately 860-930 MHz). Ambient Power (AMP) communication is currently being discussed in the Institute of Electrical and Electronics Engineers (IEEE) Task Group bp for the 802.11.bp amendment to the 802.11 standard. AMP communication is intended to enable low power operation of AMP tag devices through battery-less backscattering in a 2.4 GHz range.

### BRIEF DESCRIPTION OF THE DRAWINGS

One or more embodiments will now be described by way of example only with reference to the accompanying drawings, in which:

FIG. 1 illustrates an example of an ambient power (AMP) communication system in accordance with embodiments of the present disclosure;

FIG. 2 illustrates an example protocol for WiFi backscatter communication in accordance with embodiments of the present disclosure;

FIG. 3A illustrates example details of the AMP portion of a PPDU in accordance with one or more embodiments of the present disclosure;

FIG. 3B illustrates another example of the AMP portion of a PPDU in accordance with one or more embodiments of the present disclosure;

FIG. 4 illustrates an example of the contents of an AMP downlink (DL) SYNC field of a PPDU in accordance with one or more embodiments of the present disclosure;

FIG. 5 illustrates another example of the contents of an AMP DL SYNC field in accordance with one or more embodiments of the present disclosure;

FIG. 6 illustrates an example of an AMP DL SYNC field in accordance with one or more embodiments of the present disclosure;

FIG. 7A and FIG. 7B illustrate examples of an AMP DL SYNC field for backscattering in accordance with embodiments of the present disclosure;

FIG. 8 illustrates examples of an AMP DL SYNC field supporting dual bands in accordance with one or more embodiments of the present disclosure;

FIG. 9 illustrates further examples of an AMP DL SYNC field supporting dual bands in accordance with one or more embodiments of the present disclosure;

FIG. 10 illustrates an example of an RF front end architecture of an AMP tag;

FIG. 11 illustrates an example of an AMP tag RF front end architecture including a differential energy detector;

FIG. 12A and FIG. 12B illustrate examples of an AMP DL SYNC field including a non-Manchester encoded On-Off keying (OOK) portion and a Manchester encoded OOK portion in accordance with one or more embodiments of the present disclosure;

FIG. 12C illustrates an example of an AMP DL SYNC field including an end of SYNC portion in accordance with one or more embodiments of the present disclosure;

FIG. 13A and FIG. 13B illustrate examples of an (length 8) AMP DL SYNC field including a non-Manchester encoded OOK portion and a Manchester encoded OOK portion in accordance with one or more embodiments of the present disclosure; and

FIG. 14 is a flow chart illustrating an example method for generating an (AMP) PPDU in accordance with one or more embodiments of the present disclosure.

### DETAILED DESCRIPTION

The various implementations described in the following description relate generally to new physical layer protocol data unit (PPDU) formats and methodologies associated with Ambient Power (AMP) communications with an AMP tag device. More particularly, innovative PPDU formats are described to support multiple data communication modes (e.g., a sub-1 GHz band communication mode and a 2.4 GHz band communication mode), wireless power transfer/RF energy harvesting, ambient backscatter communications, coexistence mechanisms, and other features associated with the IEEE 802.11 bp amendment to the IEEE 802.11 standard. Briefly, the 802.11 bp amendment is intended to extend IEEE 802.11 MAC and PHY layers to support AMP stations (AMP STAs) that harvest energy for operation.

Embodiments disclosed herein are directed to a physical layer protocol data unit (PPDU) format associated with ambient power (AMP) communication with an AMP tag device that is able to co-exist with legacy WiFi devices and infrastructure in a WiFi network. In an example described more fully below, an AMP-compliant WiFi device generates a PPDU that includes a preamble that is compliant with an IEEE 802.11 standard. The PPDU further includes an AMP preamble including a synchronization (SYNC) field and an AMP data frame carrying downlink (DL) data. In this example, the SYNC field of the AMP preamble includes an On-Off keying (OOK) modulated SYNC sequence, the SYNC sequence including an indication of a first data rate or a second data rate for the DL data. The method further includes transmitting, by the WiFi device, the PPDU for reception by the AMP tag device.

As used herein, the term “non-legacy” may refer to physical layer protocol data unit (PPDU) formats and communication protocols conforming with the IEEE 802.11bn amendment to the IEEE 802.11 standard (also referred to as Ultra High Reliability or “UHR” or “Wi-Fi 8”) as well as future generations/amendments. In contrast, the term “legacy” may be used herein to refer to PPDU formats and communication protocols conforming to the IEEE 802.11be (also referred to as Extremely High Throughput or “EHT” or “Wi-Fi 7”) or IEEE 802.11ax (also referred to as High Efficiency or “HE” or “Wi-Fi 6/6E”) amendments to the IEEE 802.11 standard, or earlier generations of the IEEE 802.11 standard.

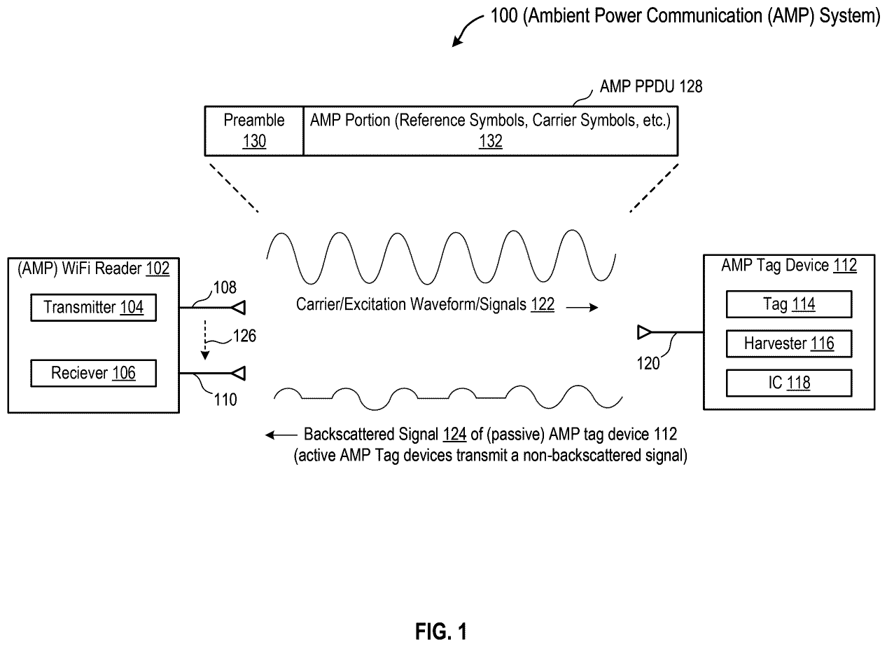

FIG. 1 illustrates an example of an ambient power (AMP) communication system 100 in accordance with embodiments of the present disclosure. The illustrated AMP communication system 100 includes an AMP tag device 112 and a WiFi reader 102 and that is AMP compliant and may operate to read (and in some cases write) data from/to the AMP tag device 112. The AMP tag device 112 and WiFi reader 102 may be implemented by one or more of analog circuitry, mixed-signal circuitry, memory circuitry, logic circuitry, and processing circuitry that executes code stored in a memory(ies) to perform disclosed functions on one or more integrated circuits.

The AMP tag device 112 may be a device compatible with the 802.11 bp amendment to the IEEE 802.11 standard. In one or more embodiments, the AMP tag device 112 can be a battery-less backscattering tag device operable in one or more frequency sub-bands, such as sub-1 GHz and 2.4 GHz (or general sub-7 GHZ) frequency bands, and have one or more antenna 120 for transmitting or receiving in the operating frequency band(s). The AMP tag device 112 is typically a low-cost device, and has an energy efficient design by using a low cost voltage controlled oscillator (VCO) with no crystal and phase lock loop (PLL). The AMP tag device 112 may also have an integrated circuit (IC) 118 to facilitate transmitting or receiving signals in the one or more frequency bands based on timing of the VCO. A received signal may indicate a request from the WiFi reader 102 to read or write data in a memory of the AMP tag device 112 (also referred to herein as tag 114) and a transmitted signal may indicate data stored in the tag 114 or a response to a write operation. The AMP tag device 112 may further include a harvester 116 which extracts power from a (energizing/excitation) waveform 122 transmitted by the AMP-compliant WiFi reader 102 and incident on the antenna 120 in order to operate the integrated circuit (IC) 118 to receive and transmit signals.

An AMP tag device 112 may include an AMP IoT device, which can as sensors, monitors, actuators, etc. for various applications that may require low cost and maintenance-free/battery-less devices and/or small form factor devices. Such applications may include, for example, smart manufacturing, environmental sensing and monitoring (e.g., in data centers), asset management, smart home sensing and monitoring, smart agriculture applications, indoor positioning, smart power grid applications, food supply chain monitoring, etc. Such devices should also be backward compatible with existing WiFi signals and communications (e.g., 20 MHz channel bandwidths, symbol-based waveforms, and higher carrier frequencies (2.4 GHz, 5 GHZ, 6 GHZ, etc.).

In one or more embodiments, the waveform 122 may be a carrier waveform or energizing (carrier) waveform on which the data transmitted by the WiFi reader 102 is modulated, and on which the AMP tag device 112 backscatters data by modulation to define the signals transmitted by the AMP tag device 112. To transmit and receive the signals, the WiFi reader 102 of this example includes a transmitter 104, receiver 106 and one or more antenna such as antenna 108 and antenna 110. The WiFi reader 102 may take the form of a smart phone, smart home hub, public transportation hotspot, dedicated reader device, etc., and be compatible with one or more legacy and/or non-legacy amendments to the IEEE 802.11 standard.

The WiFi reader 102 of this example operates to transmit and receive WiFi signals in addition to signals transmitted for the operation of the AMP tag device 112. To achieve co-existence with other legacy WiFi devices (e.g., devices which do not support AMP communication), the WiFi reader 102 is arranged to transmit the waveform 122 to the AMP tag device 112 in the form of an AMP physical layer protocol data unit (PPDU) 128 including a preamble 130 having symbols that define a legacy WiFi preamble, e.g., a 802.11b preamble or legacy orthogonal frequency division multiplexed (OFDM) preamble (e.g., 802.11g/n/ac/ax/be), and a payload/AMP portion 132 of the PPDU. By including the legacy preamble, the AMP PPDU 128 is configured to allow other WiFi readers or legacy WiFi devices (not shown and not AMP compliant) to be able to decode the legacy preamble of the AMP PPDU 128 and backoff from transmitting for the duration of the AMP PPDU 128 (as indicated by the preamble) so as not to interfere with AMP communication between the WiFi reader 102 and the AMP tag device 112.

In one or more embodiments, the WiFi reader 102 may read data from the tag 116 or write data to the tag 116 by transmitting the AMP PPDU 128. The AMP PPDU 128 transmitted as the waveform 122 is incident on the antenna 120 of the AMP tag device 112. For passive AMP tag devices 112 that rely on backscattered communications, the harvester 116 of the AMP tag device 112 may harvest power from the waveform 122 defining the AMP PPDU 128 to power the IC 118 to receive and decode symbols in an AMP portion 132 of the PPDU which is in the payload of the AMP PPDU 128. Based on the symbols that are decoded in the AMP PPDU 128, the IC 118 may cause the AMP tag device 112 perform a read or write operation and transmit a response. The AMP tag device 112 may transmit the response by a backscattering process which involves modulating a portion of the waveform 122 incident on the antenna 120 to generate a backscatter signal 124. The impedance of the antenna 120 may be modulated based on bits of the response to modulate an amount of incident RF energy and scatter the amount of incident energy on the antenna 120 to transmit bits of the response from the AMP tag device 112 to the WiFi reader 102 as backscattering. The response may be data stored in the tag 116 (e.g., an identifier associated with the tag, sensor measurement data, etc.) or a protocol compliant response control message. The WiFi reader 102 will then receive this backscatter signal 124. In some embodiments, the WiFi reader 102 may further send an acknowledgement to indicate the receipt of the response or uplink communication.

The modulation clock accuracy of AMP tag device 112 may be very limited, e.g., 100,000 parts per million (ppm) variation due to a low cost design. The ppm may be measure of a variation of modulation accuracy such as a 1 Hz change in frequency for every 1 MHz of frequency. Further, complexity associated with the reading of data may need to be put onto the WiFi reader 102 which needs to resolve a large sampling frequency offset (SFO) of the VCO of the AMP tag device 112.

In one or more embodiments, the WiFi reader 102 may need to send a well-designed waveform 122 to define the AMP PPDU 128. The waveform 122 may be the carrier waveform with a repeated base waveform. This way, signal leakage 112 from transmit antenna 108 to receive antenna 110 due to antenna coupling can be removed and the backscattered signal received by the WiFi reader 102 is able to be decoded with better signal-to-interference-and-noise ratio (SINR). The antenna coupling may be leakage of a signal transmitted by the transmitter 104 and received at the receiver 106. The waveform 122 may have defined design criteria such as a low peak to average power ratio (PAPR) to enable higher transmit power and better receive signal-to-noise ratio, a low power fluctuation for a duration of every symbol for which On-Off keying (OOK) modulation is applied for backscattering, and small spectral leakage due to the OOK. In an example, for 250 kbps OOK with Manchester encoding, a symbol duration is 2 us, while for 1 Mbps OOK with Manchester encoding, a symbol duration is 0.5 us. The OOK with Manchester encoding is a method of transmitting data where the waveform 122 is either on or off to represent a ‘1’ or ‘0’ bit, and the Manchester encoding ensures a transition occurs at the start of each bit period, aiding clock recovery and data integrity.

Signal leakage 126 may have a relatively high power and the same timing as the waveform 122, and the backscatter signal 124 received at the receiver 106 of the WiFi reader 102 may be masked by the signal leakage 126 which typically has a higher power. The WiFi reader 102 needs to remove this signal leakage 126 from a received signal at the receiver 106 to recover the backscatter signal 124 using a leakage estimation and removal process. Many ways for removing this signal leakage 126 are possible.

In one or more embodiments, a leakage in an Nth symbol of the AMP PPDU 128 that is received where N is an integer may be removed by subtracting a waveform of the N−1th symbol that is already received from a waveform of the Nth symbol. The differencing may reduce the signal leakage 126 but could result in destroying the Nth symbol modulation. In one or more embodiments, the WiFi reader 102 may transmit reference symbols in the AMP PPDU 128 and determine leakage of the reference symbols between the transmitter 104 and the receiver 106. The reference symbols may be predefined symbols that represent a predefined data sequence. Then, the WiFi reader 102 may transmit subsequent carrier symbols which the AMP tag device 112 receives in the AMP PPDU 128. The AMP tag device 112 may receive the AMP PPDU 128 and modulate data on a waveform of the carrier symbols based on backscattering to transmit data back to the WiFi reader 102, and the modulation parameters are determined based on control information in an AMP portion of the PPDU such as AMP data transmitted to the AMP tag device 112 which also includes a synchronization pattern and the reference symbols in some embodiments. The reference symbols may have a same format and content as the carrier symbols except for some phase or polarity differences, and the AMP tag device 112 does not backscatter any data within the duration of the reference symbols to allow for accurate signal leakage 126 determination. In some embodiments, the AMP tag device 112 may backscatter data bits to the WiFi reader 102 a predetermined time after sending the carrier symbols to allow for the WiFi reader 102 to estimate the signal leakage 126 based on the carrier symbols received during the non-backscattering time by the receiver 106. The WiFi reader 102 may receive the combined signal leakage 126 and backscattering signal 124 and then subtract the estimated signal leakage 126 based on reference symbols from the received signal to remove the signal leakage 126 and recover the backscatter signal 124 without the signal leakage 126.

In one or more embodiments, the WiFi reader 102 may send reference symbols periodically in the AMP PPDU 128 and instruct the AMP tag device 112 to skip performing a backscattering every N reference symbols for the WiFi reader 102 to determine the signal leakage 126. The estimation process may include estimating the reference symbols which are received based on the transmitted reference symbols to estimate the signal leakage 126. The WiFi reader 102 may then subtract, at the receiver 106, the estimated signal leakage 126 based on the reference symbols from a received signal to recover the backscatter signal 124 and remove the signal leakage 126. The periodic sending of the reference symbols or determining the signal leakage 126 allows for improving the signal leakage 126 estimation and recovery of the backscattered signal with higher signal-to-noise ratio.

In one or more embodiments, the portion of the waveform 122 that defines the reference symbols associated with leakage estimation and the carrier symbols that are backscattered may not be simple repeated symbols that cause a spectrum spike and violate transmit requirements. The portion of the waveform 122 may also be a known waveform that is received at the receiver 106 for signal leakage 126 estimation. The phase or polarity on the portion of the waveform 122 for signal leakage 126 estimation may need to be removed to perform the carrier symbol leakage estimation. In one or more embodiments, the portion of the waveform 122 may be an existing WiFi single-carrier waveform, e.g., as defined by IEEE 802.11b. The receiver 106 may need to remove any modulation (e.g., differential binary phase shift keying (DBPSK)) of 802.11b from the reference symbol portion of the waveform 122, estimate the leakage signal of the reference symbols, and regenerate carrier symbols with modulation recovered for signal leakage 126 removal. As a result, a waveform of the regenerated carrier symbols is subtracted from a received signal at the receiver 106 to recover the backscattered signal 124 resulting from backscattering a waveform of carrier symbols in the AMP PPDU 128 for signal leakage 126 removal.

While the foregoing description relates generally to backscattered communications, various methodologies described herein are likewise applicable to non-backscattered communications, such as those involving active or battery-powered tag devices that do not require (or only periodically require) an energizing waveform.

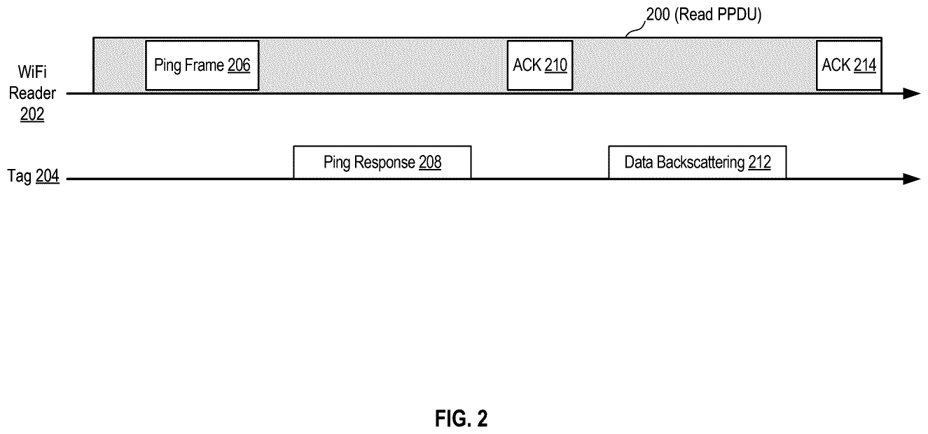

FIG. 2 illustrates an example protocol for WiFi backscatter communication in accordance with embodiments of the present disclosure. In the illustrated example, a WiFi reader 202 transmits a (read) PPDU 200 to an AMP tag 204. In this example, the PPDU 200 includes a ping frame 206 that solicits a ping response 208 from the AMP tag 204. The ping response 208 is acknowledged by ACK 210, and the AMP tag 204 performs data backscattering 212 (e.g., to provide solicited data stored in the AMP tag 204), which is then acknowledged by ACK 214. In this example, in addition to sending control information to the tag 204, the (read) PPDU 200 may serve as the energizing carrier waveform for use in generating the ping response 208 and data backscattering 212.

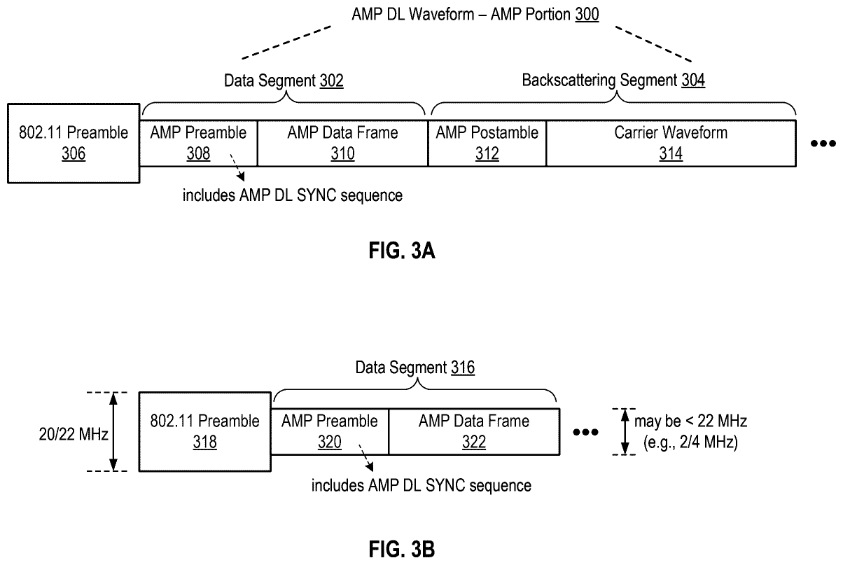

FIG. 3A illustrates example details of the AMP portion 300 of a PPDU in accordance with one or more embodiments of the present disclosure. The PPDU may be transmitted by a WiFi reader to an AMP tag device that relies on backscattered communications. In the illustrated embodiment, the AMP portion 300 is preceded by an 802.11-based preamble 306. In various examples, the preamble 306 is configured to provide coexistence with legacy WiFi devices, and may include either a 802.11b preamble or an OFDM preamble defined by 802.11g/n/ac/ax/be. The preamble 306 may indicate the duration of the entire (AMP) PPDU.

In this example, the AMP portion 300 of the PPDU is a unified AMP DL waveform that includes both a data segment 302 and a backscattering segment 304. The data segment 302 includes an AMP preamble 308 and an AMP data frame 310. As described more fully below, the AMP preamble 308 of this example includes an AMP DL synchronization (SYNC) sequence (e.g., an OOK modulated sequence) that allows a recipient device to detect the AMP preamble 308 and synchronize and calibrate reception of the AMP data frame 310. The AMP data frame 310 may carry carrier symbols modulated by the WiFi reader with data to be transmitted to an AMP tag.

The backscattering segment 304 of this example includes an AMP postamble 312 and a carrier waveform 314. The AMP postamble 312 may be included to indicate the start of the carrier waveform 314 or the end of the AMP data frame 310, and to cause other devices sharing the spectrum to continue to backoff transmissions. In an example, the carrier waveform 314 may include carrier symbols (e.g., all ON energy) which are not modulated by the WiFi reader and whose waveform is to be backscattered by a recipient AMP tag device to transmit data back to the WiFi reader as the backscatter signal 124. For example, the carrier waveform 314 can consist of a sequence of single carrier symbols having a specified bandwidth, and randomization of the polarity or phase of the symbols may be performed to mitigate spectrum spikes. Although not separately illustrated, the backscattering segment 204 may further include reference symbols that are configured to support leakage signal estimation by the WiFi reader.

The AMP portion 300 of this example may have a narrow bandwidth (e.g., 2 MHz or 4 MHz) as compared to the bandwidth of the 802.11 preamble 306 (e.g., 20/22 MHz). The narrow bandwidth may be determined, for example, by application of a DSSS spreading code that differs from a spreading code associated with the 802.11 preamble 306.

FIG. 3B illustrates another example of the AMP portion of a PPDU in accordance with one or more embodiments of the present disclosure. The PPDU of this example may be transmitted by a WiFi reader to an AMP tag device that does not rely on backscattered communications (e.g., an active AMP tag device). In the illustrated embodiment, the AMP portion 300 includes a data segment 316 but does not include a backscattering segment. The data segment 316 of this example is preceded by an 802.11-based preamble 318, and includes an AMP preamble 320 and an AMP data frame 322. In various embodiments, the AMP preamble 320 includes a SYNC sequence that differs from that of the AMP preamble 306 of FIG. 3A (e.g., to accommodate different sampling rates). The illustrated sequences of FIGS. 3A and 3B may continue with multiple data segments and/or backscattering segments.

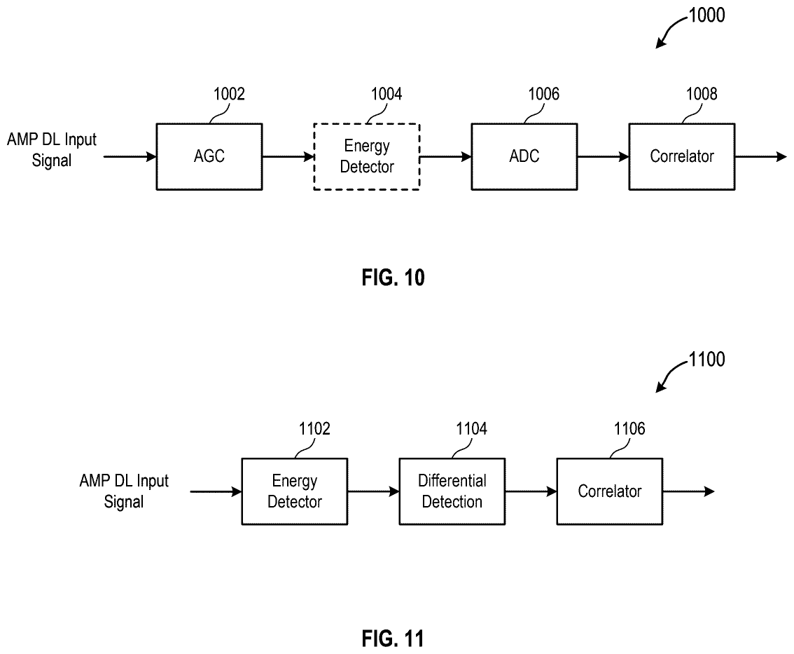

Various examples of an AMP DL SYNC field and SYNC sequences for accommodating different types of AMP tags having differing hardware capabilities are described below. For example, some “high-end” tags may have front-end gain control and ADC sampling capabilities for performing ADC correlation-based SYNC detection (see, e.g., the example of FIG. 10), while “low-end” tags may have no front-end gain control functionality and can only perform per-bit differential signal detection (see, e.g., the example of FIG. 11). In various embodiments described herein, AMP DL SYNC field designs are provided to enable SYNC detection for both high-end and low-end tags in a “unified” PPDU format.

An AMP DL PPDU can serve various types of AMP tags and enable multiple functions. For example, for AMP-assisted WiFi devices (e.g., IoT devices) the AMP DL PPDU can provide a wakeup function. For AMP-only active STAs, the AMP DL PPDU can be used for wakeup and to provide downlink control frames. For backscattering AMP tags (or AMP STAs), the AMP DL PPDU can be used for wakeup, to provide downlink control frames, and to provide an uplink carrier waveform for energy harvesting.

Various of the unified SYNC field designs described herein can support all three categories of AMP devices. Each category of AMP devices may have different hardware design limitations. For example, AMP-only active STAs can support 1000 Hz ppm, up to a 8 MHz clock rate, and a link budget of 90 dB. Backscattering AMP tags may support 10 Kppm, up to a 2 MHz clock rate, and a link budget of 30 dB. Wakeup only AMP devices may have similar capabilities as active STAs/tags, including a link budget of 90 dB. Accordingly, multiple SYNC patterns can be defined to support different types of AMP STAs.

In general, an AMP SYNC field of a unified AMP DL PPDU needs to support preamble detection for various tag categories with clock accuracy from 1000 ppm to 100,000 ppm. In an example, support for bit-level synchronization may be required for low-cost passive tags, while support for lower SNR detection may be required for a wakeup receiver or active transmitter. A 2 MHz or lower clock rate may be required for passive AMP tags, and to guarantee at least 3 sampled bits per ON/OFF period, the ON/OFF bit duration may need to be at least 2 us. The SYNC field design should further support a low miss detection probability for an AMP PPDU, a low false detection probability from noise and all energy waveforms, and a low false detection probability for OOK modulated waveforms.

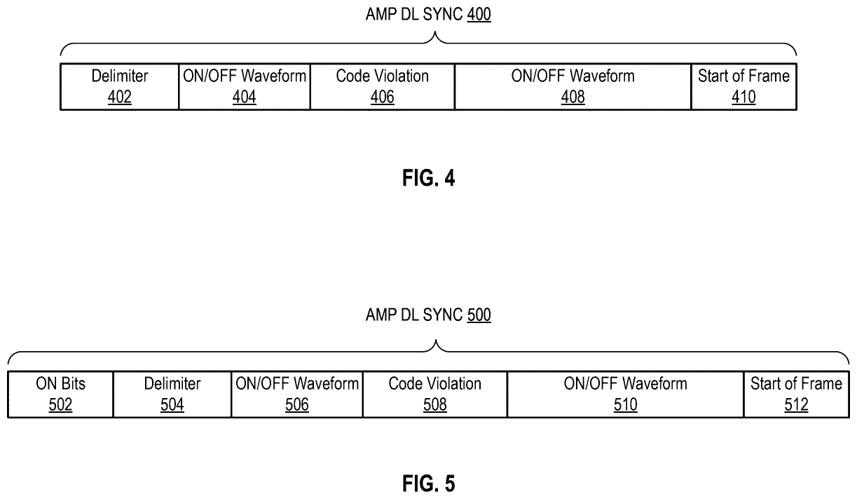

FIG. 4 illustrates an example of the contents of an AMP downlink (DL) SYNC field 400 of a PPDU in accordance with one or more embodiments of the present disclosure. In the illustrated embodiment, the AMP SYNC field 400 includes a delimiter subfield 402, an ON/OFF waveform 404, a code violation 406, an ON/OFF waveform 408, and a start of frame subfield 410. In an example, the delimiter subfield 402 is an OFF duration (e.g., 2 us or 4 us) that allows an AMP tag to preliminarily detect the start of the AMP preamble. In another example, this subfield may be omitted and an OFF waveform in the following symbol can serve the same purpose.

In an example, the ON/OFF waveform 404 includes several periods (e.g., of 2 us or longer) of an ON/OFF pattern to help detect the AMP preamble and distinguish a UHR RFID waveform or other random signal. The ON/OFF bits can be encoded as Manchester bits “1” or “0” (e.g., four ON/OFF bits). The code violation 406 can include non-Manchester encoded symbols to confirm the AMP preamble and avoid false triggers from Manchester encoded OOK data that may be transmitted by nearby devices. In an example, the code violation 406 includes 3 periods of ON or 3 periods of OFF.

In the illustrated embodiment, the ON/OFF waveform 404 serves multiple purposes. For example, some AMP tags can use this portion to further detect the AMP preamble with better detection SNR. In addition, some AMP tags may use this field to switch to a higher clock rate, resulting in 1˜2 periods of unstable data, and use the rest of the AMP DL SYNC field 400 to resynchronize timing. Further, some AMP tags may use this field to calibrate oscillator/clock accuracy. The start of frame subfield 410 may include one or more ON/OFF transitions to assist (low-end) AMP tags with synchronizing on frame timing.

FIG. 5 illustrates another example of the contents of an AMP (DL) SYNC field 500 in accordance with one or more embodiments of the present disclosure. In the illustrated embodiment, the AMP SYNC field 500 includes an ON bits subfield 502, a delimiter subfield 504, an ON/OFF waveform 506, a code violation 508, an ON/OFF waveform 510, and a start of frame subfield 512. Elements 504-512 of the AMP SYNC field correspond to similarly labeled elements 402-410 of FIG. 4. In this example, the ON bits subfield 502 includes a sequence of ON bits that are pre-appended to the SYNC sequence as gain calibration bits. The phase/polarity of the ON bits may differ to avoid spectrum leakage. The ON bits can have a predefined phase/polarity of 1 and −1, or change based on a pseudo random sequence (e.g., a 7-bit PN sequence or 11-bit PN sequence as defined in IEEE 802.11g and IEEE 802.11be).

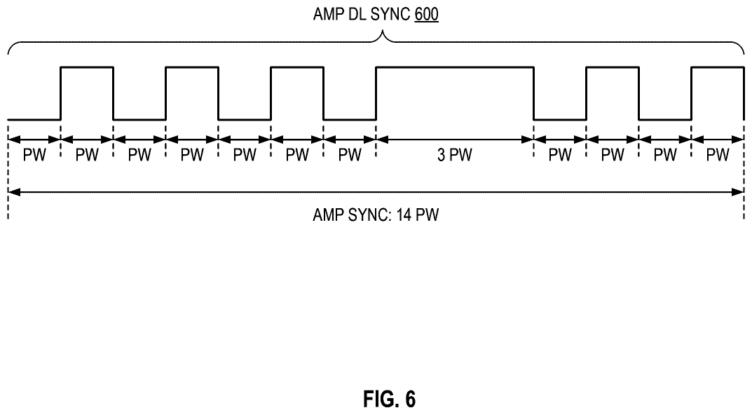

FIG. 6 illustrates an example of an AMP DL SYNC field 600 in accordance with one or more embodiments of the present disclosure. In the illustrated example, the AMP DL SYNC field 600 includes a SYNC sequence of bits having a length of 14 ON/OFF pulses/bits (e.g., with a pulse width (PW) of 2 us). In this example, the 14-bit ON/OFF SYNC sequence is: 0 1 0 1 0 1 0 1 1 1 0 1 0 1, where “1 1 1” represents a code violation. In other examples, the SYNC sequence may be 16-bit sequence such as [0 1 1 1 0 1 0 0 0 1 1 1 0 0 0 1]; [1 1 0 0 0 1 0 1 1 1 0 0 0 1 1 0]; [1 1 0 1 0 0 0 1 1 0 0 0 1 1 1 0]; or [1 1 0 0 0 1 0 1 1 0 0 0 1 1 1 0]. In another example, the SYNC sequence reuses an 802.11ba 32-bit sequence: [0 1 0 1 1 0 1 1 0 1 0 0 0 1 0 0 1 1 1 0 1 0 0 0 1 1 0 0 0 1 1 1] or [1 0 1 0 0 01 0 0 1 0 1 1 1 0 1 1 0 0 0 1 0 1 1 1 0 0 1 1 1 0 0 0].

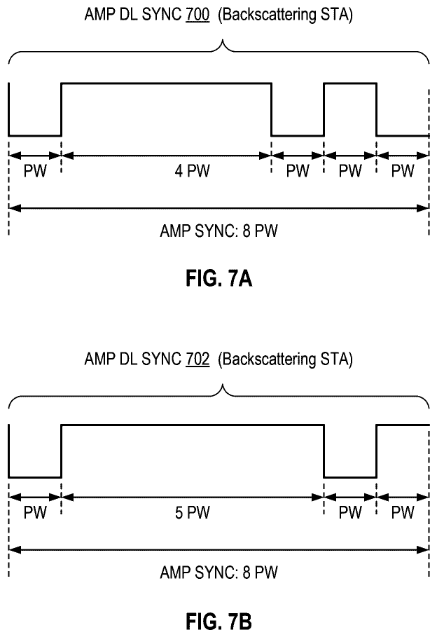

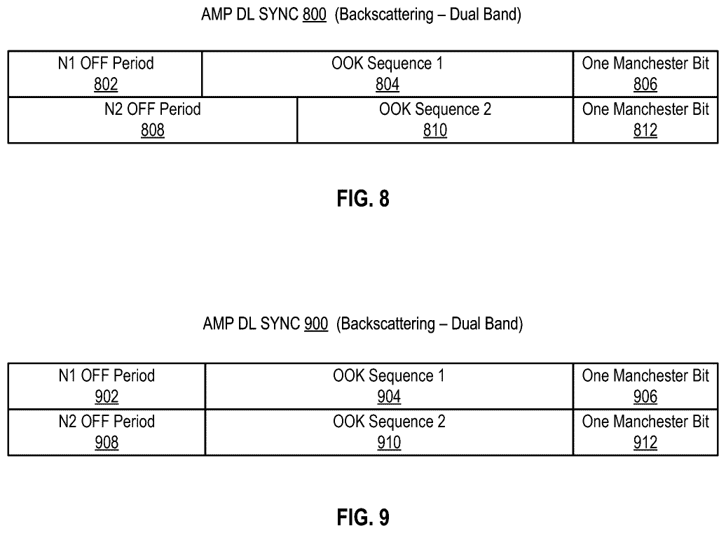

FIG. 7A and FIG. 7B illustrate examples of an AMP DL SYNC field for backscattering in accordance with embodiments of the present disclosure. An AMP tag that supports backscattering may operate with an excitation power of about-20 dBm, and the signal-to-noise ratio (SNR) is relatively high. In addition to sub-1 GHz and 2.4 GHZ operation under AMP, such an ambient powered tag (e.g., a dual-function or multi-function AMP tag) may further support UHF RFID functions. A dual/multi-function ambient powered tag with dual band support may not be able to readily distinguish different carriers in the radio frequency (RF) and analogue. The example AMP DL SYNC fields illustrated in FIGS. 7A and 7B (as well as those illustrated in FIG. 8 and FIG. 9) are single SYNC sequences and can be utilized by an AMP tag device to distinguish between sub-1 GHz and 2.4 GHz backscattering operation and, in some examples, further distinguish a UHF RFID preamble.

Referring to FIG. 7A, an example of an AMP DL SYNC field 700 for backscattering is illustrated. In this example, a SYNC sequence (or OOK waveform) of length 8 is illustrated. The SYNC sequence is formed of OOK chips or pulses (PWs) and is the same for backscattering communication in the 2.4 GHz band and the sub-1 GHz band. In an example, a 2 us pulse width is used in 2.4 GHz AMP, and an 8 us pulse width is used for sub-1 GHz AMP communications. Both values can be distinguished from a UHF 12.5 us delimiter. The SYNC sequence ends with one Manchester bit OFF/ON transition to assist timing synchronization by a recipient AMP tag. In this example, the SYNC sequence includes a 4 PW non-Manchester code violation to further indicate that an incoming signal is an AMP SYNC field. The 4 ON PW and 1 ON PW after the OFF PW can be used to avoid false triggers from a UHF RFID data portion, where the maximum ratio is 3:1. The last one Manchester bit is used to resynchronize timing for data decoding. FIG. 7B illustrates a similar AMP DL SYNC field 702, except the SYNC sequence includes a 5 PW non-Manchester code violation to further indicate that an incoming signal is an AMP SYNC

### FIELD

FIG. 8 illustrates examples of an AMP DL SYNC field 800 that further supports dual bands (e.g., sub-1 GHz AMP and 2.4 GHz AMP) in accordance with one or more embodiments of the present disclosure. In these examples, the structures of FIGS. 7A and 7B are maintained while adding signatures to aid in distinguishing 2.4 GHz AMP from sub-1 GHz AMP. In the illustrated example, the 2.4 GHz and sub-1 GHz bands are distinguished by a different number of starting zeros in the N1 OFF period that precedes OOK sequence 1 and the N2 OFF period that precedes OOK sequence 2. In a variant, the same OOK sequence may be used for both modes/frequency bands, but with different chip/pulse widths (e.g., depending on the DL data rate). In an example, a 2 us pulse width is used in 2.4 GHz AMP, and an 8 us pulse width is used for sub-1 GHz AMP communications. In a further example, the OOK sequence may include two “ON” portions. The first portion may be longer than the UHF RFID “data-0” ON to differentiate the UHF RFID preamble. The duration difference of the two ON portions can be used to avoid false triggers from a UHF RFID data portion, where the maximum ratio is approximately 3:1. The last one Manchester bit is used to resynchronize timing for data decoding. Examples of AMP DL SYNC fields having OOK sequences of various lengths include the following:

Length 5: [0 1 1 0 1], [0 1 0 0 1]
Length 6: [0 0 1 1 0 1], [0 0 1 0 0 1]
Length 7: [0 1 1 1 1 0 1], [0 1 1 0 1 0 1], [0 0 1 1 1 0 1], [0 0 1 0 1 0 1],
[0 0 0 1 1 0 1], [0 0 0 1 0 0 1], [0 0 0 1 0 1 0], [0 0 0 1 1 1 0]
Length 8: [0 1 1 1 1 0 1 0], [0 1 1 1 1 1 0 1], [0 1 1 1 0 1 0 1],
[0 0 1 1 1 1 0 1], [0 0 1 1 0 1 0 1], [0 0 0 1 1 1 0 1], [0 0 0 1 0 1 0 1],
[0 1 0 0 1 0 1], [0 0 1 1 0 0 1]
Length 9: [0 1 1 1 1 1 0 1 0]
Length 10: [0 1 1 1 1 1 0 1 0 1]

FIG. 9 illustrates further examples of an AMP DL SYNC field 900 that further supports dual bands (e.g., sub-1 GHz AMP and 2.4 GHz AMP) in accordance with one or more embodiments of the present disclosure. In these examples, the structures of FIGS. 7A and 7B are maintained and the number of starting zeros in the N OFF period is the same for each band, and the bands are distinguished by using different signature sequences (OOK sequence 1 and OOK sequence 2). The last one Manchester bit is used to resynchronize timing for data decoding. Examples of OOK sequences 1/2 of various lengths include the following:

Length 4: [0 0 0 1], [0 1 0 1], [0 0 1 0]
Length 5: [0 1 1 0 1], [0 0 0 1 0], [0 0 1 1 0]
Length 6: [0 1 0 1 0 1], [0 0 1 0 0 1], [0 0 0 1 0 1], [0 1 1 1 0 1],
[0 0 0 1 0 1], [0 0 1 1 0 1]
Length 7: [0 1 1 0 0 0 1], [0 0 0 1 1 0 1], [0 1 1 1 1 0 1], [0 0 0 1 1 0 1],
[0 0 1 1 1 0 1], [0 0 1 0 1 0 1], [0 0 0 1 0 0 1]
Length 8: [0 1 1 1 1 1 0 1], [0 1 1 1 1 0 1 0], [0 0 0 1 1 1 0 1],
[0 0 1 1 1 1 0 1], [0 1 1 0 0 1 0 1], [0 0 0 1 1 1 0 1],
[0 1 0 1 1 0 0 1]

FIG. 10 illustrates an example of an RF front end architecture 1000 of an AMP non-backscattering tag. The illustrated RF front end architecture 1000 includes an Automatic Gain Control (AGC) circuitry 1002, an (optional) energy detector 1004, an Analog-to-Digital converter (ADC) 1006, and a correlator 1008. In this example, the AMP tag may be considered a “high-end” tag having front-end gain control and ADC sampling capabilities for performing ADC correlation-based SYNC detection.

FIG. 11 illustrates an example of an AMP non-backscattering tag RF front end architecture 1100 including an energy detector 1102, differential detection 1104, and a correlator 1106. In this example, the AMP tag may be considered a “low-end” tag having no front-end gain control functionality and only performing per-bit differential signal detection.

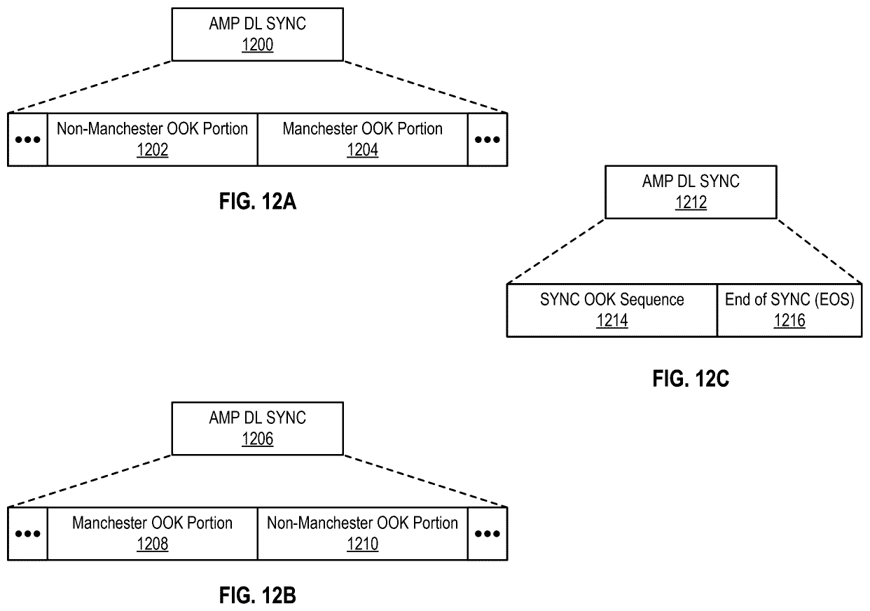

FIG. 12A and FIG. 12B illustrate examples of an AMP DL SYNC field including a non-Manchester encoded On-Off keying (OOK) portion and a Manchester encoded OOK portion in accordance with one or more embodiments of the present disclosure. The AMP DL SYNC fields of these examples can accommodate the design requirements of different types of AMP tag devices (e.g., dual/tri mode devices) which may operate in different frequency bands.

In the example illustrated by FIG. 12A, an AMP DL SYNC field 1200 includes a non-Manchester (encoded) OOK portion 1202 followed by a Manchester OOK portion 1204. In the example illustrated by FIG. 12B, an AMP DL SYNC field 1206 includes a Manchester OOK portion 1208 followed by a non-Manchester OOK portion 1210. In other examples, the AMP DL SYNC field includes multiple Manchester OOK portions and multiple non-Manchester OOK portions. Various combinations may include: multiple Manchester OOK portions+one non-Manchester OOK portion; multiple Manchester OOK portions+multiple non-Manchester OOK portions; and multiple non-Manchester OOK portions+one Manchester OOK portion. Each Manchester OOK portion can be structured before, after, or in between a non-Manchester OOK portion, and each non-Manchester OOK portion can be structured before, after, or in between a Manchester OOK portion. In the foregoing examples, each non-Manchester OOK portion consists of M (M 2:1) continuous non-Manchester OOK sequences. The Manchester OOK portion is mainly used for bit checks to reduce the rate of false triggering. The non-Manchester OOK portion is mainly used for correlation-based AMP DL receivers.

FIG. 12C illustrates an example of an AMP DL SYNC field 1212 including a SYNC sequence 1214 (OOK “ON”/“OFF”) concatenated with an end of SYNC (EOS) portion 1216. The SYNC sequence 1214 is designed for the tag to detect the start of PPDU and indicate a data rate, while the EOS portion 1216 may help to mitigate false triggers. In general, the SYNC sequence 1214 should have good auto-correlation properties with low sidelobe. The EOS portion 1216 can be a Manchester encoded waveform, another OOK sequence, and/or a mixed non-Manchester OOK portion and Manchester OOK portion. In the last example, the non-Manchester OOK portion can be used to suppress the sidelobe after the peak of SYNC correlation output, and the chip duration of the additional non-Manchester OOK portion may be the same or different from the chip duration of the SYNC sequence 1214.

In the examples of FIGS. 12A-12C, the AMP DL data rate may be indicated in different ways. In a first example, the OOK chip duration of the AMP DL SYNC field is set to half the length of a Manchester encoded OOK symbol in the corresponding data frame according to the data rate. In various embodiments, for example, one chip has a length of 2 us for a 250 kbps data rate, and one chip has length of 0.5 us for a data rate of 1 Mbps (PW=1 us). In a second example, the chip duration of the AMP DL SYNC field is a fixed value regardless of the data rate. In this example, the chip duration is the same as the lowest supported data rate (e.g., one chip=2 us). Alternatively, the chip rate may be different from any data rate in order to mitigate false triggers (e.g., one chip=1 us or 3 us).

In other examples, a SYNC sequence for non-backscattering operation has an AMP SYNC field that is the same length for both a first data rate and a second data rate (e.g., through the use of different sampling rates). In an example, the SYNC sequence includes a basic sequence S to indicate the first data rate and a complementary sequence S to indicate the second data rate. In another example, the SYNC sequence includes a basic sequence S to indicate the first data rate and a sequence [S̅, S̅] to indicate the second data rate. In a further example, the first data rate is 250 Kilobits per second (Kbps) and the second data rate is 1 Megabits per second (Mbps). In yet another example, the AMP SYNC field/AMP preamble duration is the same for different data rates, but with different sampling rates. An example is shown below:

[1 1 1 1 1 1 1 1 0 0 0 0 0 0 0 0 1 1 1 1 0 0 0 0 0 0 0 0 1 1 1 1] - for a low
rate sequence, and
[1 0 1 0 1 0 1 0 0 1 0 1 0 1 0 1 1 0 1 0 0 1 0 1 0 1 0 1 1 0 1 0] - for a high
rate sequence.

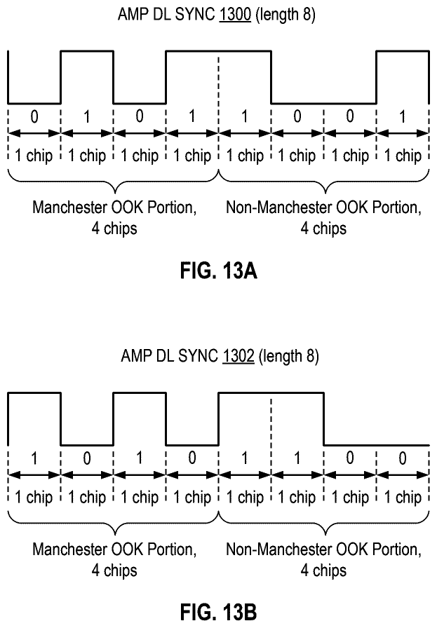

FIG. 13A and FIG. 13B illustrate examples of an (length 8) AMP DL SYNC field including a non-Manchester encoded OOK portion and a Manchester encoded OOK portion in accordance with one or more embodiments of the present disclosure. The AMP DL SYNC fields of these examples can facilitate SYNC detection for both high-end tags (e.g., utilizing ADC correlation-based SYNC detection) and low-end tags (e.g., utilizing per-bit differential detection). Referring first to FIG. 13A, an AMP DL SYNC field 1300 having an length of 8 (chips) is illustrated. In this example, the OOK waveform (or sequence) is [0 1 0 1 1 0 0 1], where the first four chips are a Manchester encoded OOK portion and the second four chips are a non-Manchester encoded OOK portion. In the AMP DL SYNC field 1302 shown in FIG. 13B, the OOK waveform is [1 0 1 0 1 1 0 0], where the first four chips are a Manchester encoded OOK portion and the second four chips are a non-Manchester encoded OOK portion. Various other examples of an AMP DL SYNC field of different lengths are shown below, where 1 corresponds to an ON chip and 0 corresponds to an OFF chip.

AMP DL SYNC field—examples of length 8 OOK waveform:

−[0 1 1 1 1 0 1 0]
−[1 0 0 1 1 0 1 0]
−[1 0 1 0 0 1 1 0]
−[0 1 1 0 1 0 1 0]
−[0 1 0 1 0 1 1 0]
−[1 0 1 0 1 0 0 1]
−[1 0 0 1 0 1 0 1]
−[1 0 1 1 1 0 0 0]
−[1 1 1 0 0 1 0 0]
−[0 1 1 1 0 1 0 0]
−[1 1 1 0 0 1 0 0]
−[0 1 1 1 0 0 1 0]
−[1 1 0 0 1 0 1 0]
−[0 0 1 1 1 0 1 0]
−[0 1 0 0 1 1 1 0]
−[0 0 1 0 1 1 1 0]
−[0 0 1 1 0 1 0 1]

AMP DL SYNC field—examples of length 12 OOK waveform:

−[0 1 1 1 0 0 0 1 0 0 1 1]
−[1 0 0 0 1 1 1 0 1 1 0 0]
−[0 1 1 1 0 0 1 1 0 1 0 0]
−[0 1 1 0 0 1 1 1 0 1 0 0]
−[0 1 1 1 0 1 0 0 1 1 0 0]
−[0 1 0 1 1 1 0 0 1 1 0 0]
−[0 1 1 1 0 0 1 0 1 1 0 0]
−[0 1 1 0 1 0 0 1 1 1 0 0]
−[0 1 0 1 1 0 0 1 1 1 0 0]
−[0 1 1 0 0 1 0 1 1 1 0 0]
−[0 1 0 0 1 1 0 1 1 1 0 0]
−[0 1 1 0 1 1 0 1 0 1 0 0]
−[0 1 0 1 0 1 1 0 1 1 0 0]
−[0 1 1 1 0 1 0 0 0 1 1 0]
−[0 1 1 1 0 0 0 1 0 1 1 0]
−[0 1 1 0 1 0 0 0 1 1 1 0]
−[0 1 1 0 0 0 1 0 1 1 1 0]
−[0 0 1 1 0 1 1 0 1 0 1 0]
−[0 0 1 0 1 0 1 1 0 1 1 0]
−[0 1 1 0 1 0 0 0 1 1 1 0]
−[1 0 0 1 0 1 1 1 0 0 0 1]
−[1 1 0 0 1 0 0 1 0 1 0 1]
−[1 0 0 1 1 1 1 0 1 0 0 0]
−[0 1 0 1 1 0 1 1 1 0 0 0]
−[1 0 0 1 0 1 1 1 1 0 0 0]
−[1 0 1 1 0 0 1 1 1 0 0 0]
−[0 1 1 0 1 0 1 1 1 0 0 0]
−[1 0 1 0 0 1 1 1 1 0 0 0]
−[0 1 0 1 1 1 1 0 0 1 0 0]
−[0 1 1 1 0 0 1 1 0 1 0 0]
−[1 1 0 0 0 1 1 1 0 1 0 0]
−[1 0 1 1 0 0 0 1 1 1 0 0]
−[0 1 1 1 1 0 1 0 0 0 1 0]
−[0 1 0 1 1 1 1 0 0 0 1 0]
−[0 1 1 1 0 1 0 1 0 0 1 0]
−[1 1 1 0 0 0 1 1 0 0 1 0]
−[0 1 1 1 1 0 0 1 0 0 0 1]
−[1 0 1 1 0 1 0 1 0 0 0 1]
−[1 1 0 1 0 0 1 1 0 0 0 1]
−[1 1 1 0 0 0 1 0 1 0 0 1]
−[1 0 0 1 1 0 1 0 1 1 0 0]
−[0 1 0 1 0 1 1 0 1 1 0 0]
−[1 0 1 0 1 0 0 1 1 1 0 0]
−[0 1 1 0 1 0 0 1 1 1 0 0]
−[1 0 0 1 0 1 0 1 1 1 0 0]
−[1 0 1 0 1 0 0 1 0 0 1 1]
−[0 0 1 1 1 0 1 0 1 1 0 0]
−[0 0 1 1 1 0 0 1 1 0 1 0]
−[0 0 0 1 1 1 0 1 1 0 1 0]

AMP DL SYNC field—examples of length 16 OOK waveform:

−[0 0 1 1 0 1 1 0 1 0 1 0 0 0 1 1]
−[0 0 1 1 1 0 1 0 1 0 0 1 0 0 1 1]
−[0 1 1 0 0 0 1 1 1 0 1 1 0 1 0 0]
−[0 1 1 0 1 1 0 0 0 1 1 1 0 1 0 0]
−[0 1 0 1 1 1 0 0 0 1 1 0 1 1 0 0]
−[0 1 1 1 0 0 0 1 0 1 1 0 1 1 0 0]
−[0 1 0 1 1 0 1 1 0 0 0 1 1 1 0 0]
−[0 1 1 1 0 1 0 0 1 0 0 1 1 1 0 0]
−[1 0 0 0 1 0 1 0 1 1 0 1 0 0 1 1]
−[1 0 0 1 0 0 1 1 0 0 1 0 1 0 1 1]
−[0 1 1 0 1 1 0 0 1 1 0 1 0 1 0 0]
−[0 1 1 1 0 1 0 1 0 0 1 0 1 1 0 0]
−[0 1 1 1 0 0 1 1 0 1 0 0 0 1 0 1]
−[0 1 1 0 0 0 1 1 1 0 1 0 0 1 0 1]
−[0 1 1 1 0 0 1 0 0 0 1 0 1 1 0 1]
−[0 1 1 1 0 0 1 0 1 0 1 1 0 0 1 0]
−[0 1 0 0 1 1 0 1 0 1 1 1 0 0 1 0]
−[0 1 1 0 1 1 0 1 0 1 0 0 0 1 1 0]
−[0 1 0 1 0 1 1 0 0 1 0 0 1 1 1 0]
−[0 1 1 0 0 1 0 1 0 1 0 0 1 1 1 0]
−[0 0 1 1 0 1 0 0 1 0 1 0 1 1 1 0]
−[1 1 0 0 1 0 1 1 0 1 0 1 0 0 0 1]
−[1 0 0 1 1 0 1 0 1 0 1 1 0 0 0 1]
−[1 0 1 0 1 0 0 1 1 0 1 1 0 0 0 1]
−[1 0 0 1 0 0 1 0 1 0 1 1 1 0 0 1]
−[1 0 1 1 0 0 1 0 1 0 0 0 1 1 0 1]
−[1 0 0 0 1 1 0 1 0 1 0 0 1 1 0 1]
−[0 1 0 1 1 0 0 1 1 1 1 0 1 0 0 0]
−[0 0 1 1 1 0 1 0 1 1 0 1 1 0 0 0]
−[1 0 1 0 0 0 1 1 1 1 0 1 1 0 0 0]
−[0 1 0 1 1 0 1 1 0 0 1 1 1 0 0 0]
−[1 0 0 1 0 1 1 1 1 1 0 0 0 1 0 0]
−[1 0 0 0 1 1 1 1 0 1 1 0 0 1 0 0]
−[1 0 1 0 1 0 0 1 1 1 1 0 0 1 0 0]
−[0 1 1 0 1 0 0 1 1 1 0 1 0 1 0 0]
−[1 0 1 1 0 1 0 1 0 0 0 1 1 1 0 0]
−[1 0 1 1 0 0 1 0 1 0 0 1 1 1 0 0]
−[0 1 0 1 0 1 1 1 1 0 0 1 0 0 1 0]
−[0 0 1 1 1 1 1 0 0 1 0 1 0 0 1 0]
−[0 1 0 1 1 1 1 0 0 0 1 1 0 0 1 0]
−[1 1 1 0 0 0 1 0 1 0 0 1 1 0 0 1]
−[0 1 1 0 1 0 0 1 1 0 0 1 1 1 0 0]
−[0 1 1 0 1 0 0 1 0 1 0 1 1 1 0 0]
−[1 0 1 0 1 0 0 1 0 0 1 1 1 1 0 0]
−[0 0 0 1 1 0 1 1 0 1 0 1 1 1 0 0]
−[0 0 0 1 1 1 1 0 1 0 1 1 0 0 1 0]
−[0 0 0 1 1 1 1 0 1 0 1 1 0 0 1 0]
−[0 0 0 1 1 1 1 0 1 0 1 0 0 1 1 0]
−[0 0 1 0 1 1 0 1 1 1 0 1 0 0 0 1]
−[0 0 1 1 1 1 0 0 1 0 0 1 0 1 0 1]

AMP DL SYNC field—examples of length 24 OOK waveform:

−[0 1 1 1 0 1 0 0 0 1 1 0 0 0 1 1 1 0 1 1 0 1 0 0]
−[0 1 1 1 0 0 0 1 0 0 1 1 1 0 0 1 0 1 1 1 0 1 0 0]
−[1 0 0 1 1 1 0 0 1 0 0 1 1 0 1 1 0 1 0 1 0 1 0 0]
−[1 0 0 1 1 0 1 0 0 1 1 0 1 0 1 0 1 1 0 1 0 1 0 0]
−[0 1 1 0 0 1 0 1 1 0 0 1 0 1 0 1 0 0 1 0 1 0 1 1]
−[0 1 1 0 0 0 1 1 0 1 1 0 0 1 0 0 1 0 1 0 1 0 1 1]
−[1 1 0 0 1 0 0 1 1 1 0 0 0 1 1 1 0 1 0 1 0 0 1 0]
−[1 1 0 0 1 0 0 0 1 1 1 0 1 0 0 1 1 1 0 1 0 0 1 0]
−[1 1 0 0 0 1 1 0 1 0 1 0 0 0 1 1 1 0 1 1 0 0 1 0]
−[1 1 0 0 1 0 0 1 1 1 0 1 0 0 0 1 1 1 0 0 1 0 1 0]
−[1 1 0 1 0 0 1 0 0 1 1 1 0 0 0 1 1 1 0 1 0 0 0 1]
−[1 1 0 1 0 0 1 0 0 1 1 1 0 1 0 0 0 1 1 1 0 0 0 1]
−[0 0 1 0 1 1 0 1 1 0 0 0 1 0 1 1 1 0 0 0 1 1 1 0]
−[0 0 1 0 1 1 0 1 1 0 0 0 1 1 1 0 0 0 1 0 1 1 1 0]
−[0 0 1 1 0 1 1 0 0 0 1 0 1 1 1 0 0 0 1 1 0 1 0 1]
−[0 0 1 1 0 1 1 1 0 0 0 1 0 1 1 0 0 0 1 0 1 1 0 1]
−[0 0 1 1 0 1 1 0 0 0 1 1 1 0 0 0 1 0 1 0 1 1 0 1]
−[1 1 0 0 1 1 0 0 1 0 1 0 1 0 1 0 1 1 0 1 0 0 1 0]
−[1 0 1 0 1 0 1 0 0 1 1 0 0 1 1 0 1 1 0 1 0 0 1 0]
−[1 0 1 0 1 0 0 1 1 0 1 0 1 1 0 1 0 0 1 1 0 0 1 0]
−[1 0 1 0 1 0 1 0 0 1 0 1 1 0 1 1 0 0 1 1 0 0 1 0]
−[1 0 0 1 1 0 0 1 1 0 1 1 0 1 0 0 1 0 1 0 1 0 1 0]
−[1 1 0 0 1 1 0 0 1 0 0 1 0 1 1 0 1 0 1 0 1 0 1 0]
−[1 0 0 1 0 1 1 0 1 1 0 1 0 0 0 1 1 0 1 0 1 0 1 0]
−[1 0 0 1 0 1 1 0 1 0 0 1 1 0 0 1 1 0 1 0 1 0 1 0]
−[1 0 0 1 1 0 1 0 0 0 1 0 1 0 1 1 0 1 0 1 1 0 1 0]
−[0 1 1 0 0 1 1 0 0 0 1 0 1 0 1 0 1 1 0 1 1 0 1 0]
−[0 1 0 1 1 0 1 1 0 1 0 1 0 1 0 0 0 1 1 0 0 1 1 0]
−[1 0 1 0 1 0 1 0 1 1 0 1 0 0 1 0 0 1 1 0 0 1 1 0]
−[1 0 0 1 0 1 1 0 1 0 1 0 1 0 1 0 0 1 1 0 0 1 1 0]
−[1 0 1 0 1 0 1 0 0 1 0 1 1 0 1 0 0 1 1 0 0 1 1 0]
−[1 0 1 0 1 0 0 1 0 1 0 1 1 0 0 1 0 1 1 0 0 1 1 0]
−[1 0 0 1 1 0 0 1 1 0 1 0 1 0 1 0 1 0 0 1 0 1 1 0]
−[1 0 0 1 1 0 0 1 0 1 0 1 0 1 1 0 1 0 0 1 0 1 1 0]
−[1 0 1 0 1 0 0 1 1 0 1 0 1 0 0 1 1 0 0 1 0 1 1 0]
−[1 0 0 1 1 0 1 0 0 1 1 0 1 0 1 0 0 1 0 1 0 1 1 0]
−[1 0 0 1 0 1 1 0 1 0 0 1 1 0 0 1 0 1 0 1 0 1 1 0]
−[1 0 0 1 1 0 0 1 1 0 1 0 0 1 0 1 0 1 0 1 0 1 1 0]
−[0 1 1 0 0 1 0 1 1 0 0 1 0 1 0 1 1 0 1 0 1 0 0 1]
−[0 1 1 0 0 1 1 0 1 0 1 0 1 0 0 1 0 1 1 0 1 0 0 1]
−[0 1 1 0 0 1 1 0 0 1 0 1 0 1 0 1 0 1 1 0 1 0 0 1]
−[0 1 0 1 0 1 0 1 1 0 1 0 0 1 0 1 1 0 0 1 1 0 0 1]
−[0 1 1 0 1 0 0 1 0 1 0 1 0 1 0 1 1 0 0 1 1 0 0 1]
−[0 1 0 1 0 1 0 1 0 0 1 0 1 1 0 1 1 0 0 1 1 0 0 1]
−[0 1 1 0 1 0 0 1 0 1 1 0 0 1 1 0 0 1 0 1 0 1 0 1]
−[0 1 1 0 1 0 0 1 0 0 1 0 1 1 1 0 0 1 0 1 0 1 0 1]
−[0 0 1 1 0 0 1 1 0 1 1 0 1 0 0 1 0 1 0 1 0 1 0 1]
−[0 1 1 0 0 1 1 0 0 1 0 0 1 0 1 1 0 1 0 1 0 1 0 1]
−[0 1 0 1 0 1 0 1 1 0 1 0 0 1 0 0 1 1 0 0 1 1 0 1]
−[0 1 0 1 0 1 1 0 0 1 0 1 0 0 1 0 1 1 0 0 1 1 0 1]
−[0 1 0 1 0 1 0 1 1 0 0 1 1 0 0 1 0 0 1 0 1 1 0 1]
−[0 0 1 1 0 0 1 1 0 1 0 1 0 1 0 1 0 0 1 0 1 1 0 1]
−[0 1 0 1 0 1 0 0 1 1 1 0 0 1 0 1 1 0 1 1 0 0 1 0]
−[0 1 0 0 1 1 1 1 0 0 0 1 1 0 1 1 1 0 1 0 1 0 0 0]
−[1 0 0 1 0 1 0 0 0 1 1 1 1 1 1 0 0 1 1 0 1 0 0 0]
−[1 0 0 1 0 1 0 0 0 1 1 1 1 1 1 0 1 0 0 1 1 0 0 0]
−[1 0 1 0 1 0 1 0 0 1 0 0 1 1 1 0 0 1 1 1 1 0 0 0]
−[0 1 1 0 1 0 1 1 0 0 1 0 1 0 0 0 1 1 1 1 1 0 0 0]
−[1 0 0 0 1 1 0 1 1 0 1 0 0 1 1 1 0 1 0 1 0 1 0 0]
−[0 0 1 1 1 0 0 1 1 0 1 1 0 0 1 0 1 1 0 1 0 1 0 0]
−[1 0 1 0 1 0 1 1 0 0 0 1 1 0 0 1 0 1 1 0 1 1 0 0]
−[1 0 0 0 1 0 1 0 1 1 0 1 1 1 1 1 0 0 0 1 0 0 1 0]
−[0 1 1 1 0 0 0 1 1 0 1 0 1 0 0 1 1 0 1 1 0 0 1 0]
−[0 0 1 0 1 1 0 1 1 0 1 1 1 0 1 0 0 0 1 1 0 0 0 1]
−[0 1 1 1 0 1 0 0 0 1 0 1 0 1 1 0 1 0 1 1 0 0 0 1]
−[1 0 0 1 0 1 0 1 1 0 0 1 0 0 1 1 1 1 0 0 1 1 0 0]
−[1 0 0 0 1 1 0 0 0 1 0 1 1 1 0 1 1 0 1 1 0 1 0 0]
−[0 0 1 1 1 0 0 1 0 1 0 1 0 1 1 0 1 1 0 1 1 0 0 0]
−[0 0 1 1 0 0 1 0 1 1 1 1 0 1 0 1 0 0 1 1 0 1 0 0]
−[0 1 0 0 1 1 0 0 1 0 1 0 1 1 1 1 0 0 1 0 1 1 0 0]
−[1 0 0 0 1 1 0 1 0 1 0 1 1 0 0 1 0 1 1 0 1 1 0 0]
−[0 0 0 1 1 0 1 1 0 1 1 0 1 0 1 0 1 0 0 1 1 1 0 0]
−[0 0 1 1 0 1 0 0 1 1 1 1 0 1 0 1 0 0 1 1 0 0 1 0]
−[1 0 0 0 1 1 1 0 1 0 1 0 0 1 0 1 1 0 1 1 0 0 1 0]
−[0 1 1 1 0 0 1 1 0 0 0 1 0 1 0 0 1 1 0 1 1 0 1 0]
−[0 1 0 0 1 1 0 1 1 0 0 1 0 1 0 1 1 0 0 0 1 1 1 0]
−[0 1 0 1 1 0 1 1 0 0 1 0 1 0 0 0 1 1 0 0 1 1 1 0]

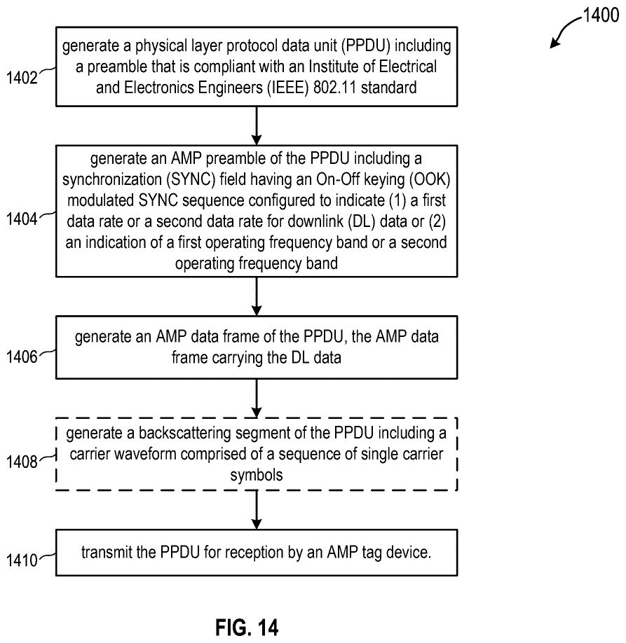

FIG. 14 is a flow chart illustrating an example method 1400 for generating an (AMP) PPDU in accordance with one or more embodiments of the present disclosure. The method 1400 can be performed by an AMP-compliant WiFi reader, such as the WiFi reader 102 described with reference to FIG. 1. The method 1400 may be utilized, for example, to perform AMP communications with a variety of active or passive AMP tag devices (e.g., in accordance with the 802.11 bp amendment to the IEEE 802.11 standard).

The method begins at step 1402, where the WiFi reader generates a PPDU including a preamble that is compliant with an IEEE 802.11 standard. The method continues at step 1404 where the WiFi reader generates an AMP preamble of the PPDU, including a synchronization (SYNC) field having an On-Off keying (OOK) modulated SYNC sequence configured to indicate a first data rate or a second data rate for downlink (DL) data and/or an indication of a first operating frequency band or a second operating frequency band. The illustrated method continues at step 1406, where the WiFi reader generates an AMP data frame of the PPDU to carry the DL data. The method continues at (optional) step 1408 where, for backscattering AMP communication, the WiFi reader generates a backscattering segment of the PPDU that includes a carrier waveform comprised of a sequence of single carrier symbols. The WiFi reader transmits (at step 1410) the PPDU for reception by an AMP tag device.

While the innovative aspects of the present disclosure have been generally described in the context of the 802.11 bp amendment to the IEEE 802.11 standard, a person having ordinary skill in the art will readily recognize that teachings and concepts herein may be applied to other wireless networks and standards including, for example, Long Term Evolution (LTE) standards and Bluetooth standards.

The innovative apparatus, frame formats, and methods illustrated in the figures and described herein enable ambient power (AMP) communications that are compatible with legacy WiFi devices and support AMP tag devices having varying communication capabilities. In an illustrative, non-limiting embodiment, a method for communicating with an ambient power (AMP) tag device by an AMP-compliant WiFi device is provided. The method includes generating a physical layer protocol data unit (PPDU), the PPDU including a preamble that is compliant with an Institute of Electrical and Electronics Engineers (IEEE) 802.11 standard. The PPDU further includes an AMP preamble including a synchronization (SYNC) field and an AMP data frame carrying downlink (DL) data, wherein the SYNC field of the AMP preamble includes an On-Off keying (OOK) modulated SYNC sequence that includes an indication of a first data rate or a second data rate for the DL data, or an indication of a first operating frequency band or a second operating frequency band. The method further includes transmitting, by the WiFi device, the PPDU for reception by the AMP tag device.

The method of this embodiment includes optional aspects. With one optional aspect, the SYNC sequence is different for backscattering operation and non-backscattering operation. In another optional aspect, the SYNC sequence is for backscattering operation and includes an initial OFF portion, at least one non-Manchester encoded code violation portion, and at least one Manchester encoded portion. In yet another optional aspect, the initial OFF portion has a first duration to indicate the first operating frequency band and a second duration to indicate a second operating frequency band.

In another optional aspect, the SYNC sequence is for backscattering operation and the SYNC field has the same OOK sequence for both the first operating frequency band and the second operating frequency band. In a further optional aspect, the SYNC sequence is for non-backscattering operation and a duration of the SYNC field is the same for both the first data rate and the second data. In another optional aspect, the SYNC sequence is for non-backscattering operation and a duration of the SYNC field is the same for both the first data rate and the second data rate.

In another optional aspect, the SYNC sequence includes a basic sequence S to indicate the first data rate and a complementary sequence S to indicate the second data rate. In a further optional aspect, the SYNC sequence includes a basic sequence S to indicate the first data rate and a sequence [S̅, S̅] to indicate the second data rate. In yet another optional aspect, the first data rate is 250 Kilobits per second (Kbps) and the second data rate is 1 Megabits per second (Mbps). In a further optional aspect, the AMP preamble is for non-backscattering operation and further includes an end of SYNC portion. In a further optional aspect, the SYNC sequence has a pulse width (PW) duration of 2 microseconds (us) for a 2.4 GHz operating frequency band. In another optional aspect, the SYNC sequence has a pulse width (PW) duration of 8 microseconds (us) for a sub-1 GHz operating frequence band.

In another optional aspect, the SYNC sequence further includes at least four consecutive “ON” pulses. In another optional aspect, the SYNC sequence is formed of pulses having a first pulse width to indicate a first data rate and a second pulse width to indicate a second data rate. In a further optional aspect, the SYNC sequence includes a first ON portion having a first duration and a second ON portion having a second duration, and wherein the ratio of the first duration and the second duration is greater than 3:1. In another optional aspect, the SYNC sequence is [0 1 1 1 1 0 1 0]. In another optional aspect, the PPDU further includes a backscattering segment, the backscattering segment including a carrier waveform configured to provide power to an AMP tag device to backscatter information to the AMP-compliant WiFi device. In a further optional aspect, the AMP preamble and AMP data frame are compliant with an IEEE 802.11 bp amendment to the IEEE 802.11 standard.

With another illustrative, non-limiting embodiment, a method for communicating with an ambient power (AMP) tag device by an AMP-compliant WiFi device is provided. The method includes generating a physical layer protocol data unit (PPDU) having a preamble that is compliant with an Institute of Electrical and Electronics Engineers (IEEE) 802.11 standard, an AMP preamble including a synchronization (SYNC) field, and an AMP data frame carrying downlink (DL) data, wherein the SYNC field of the AMP preamble includes an On-Off keying (OOK) modulated SYNC sequence, the SYNC sequence including an indication of a first operating frequency band or a second operating frequency band. The PPDU further includes a backscattering segment including a carrier waveform comprised of a sequence of single carrier symbols. The method of this embodiment further includes transmitting, by the WiFi device, the PPDU for reception by the AMP tag device.

This second embodiment includes optional aspects. With one optional aspect, the carrier waveform comprises a repeated base waveform. In another optional aspect, the SYNC sequence includes at least one Manchester encoded portion and at least one non-Manchester encoded portion. In a further optional aspect, the SYNC sequence includes at least one code violation subfield. In yet another optional aspect, the MP preamble and AMP data frame are compliant with an IEEE 802.11 bp amendment to the IEEE 802.11 standard.

In another illustrative, non-limiting embodiment, an ambient power (AMP)-compliant WiFi device includes one or more wireless transceivers and one or more processors operably coupled to the one or more wireless transceivers. The one or more processors are arranged to generate a PPDU including a preamble that is compliant with an Institute of Electrical and Electronics Engineers (IEEE) 802.11 standard. The PPDU further includes an AMP preamble including a synchronization (SYNC) field and an AMP data frame carrying downlink (DL) data, wherein the SYNC field of the AMP preamble includes an On-Off keying (OOK) modulated SYNC sequence that includes an indication of a first data rate or a second data rate for the DL data or an indication of a first operating frequency band or a second operating frequency band. The one or more processors of the WiFi device are further arranged to transmit, via the one or more wireless transceivers, the PPDU for reception by an AMP tag device.

This third embodiment includes optional aspects. With one optional aspect, the PPDU further includes a backscattering segment, the backscattering segment including a carrier waveform having a repeated base waveform. In another optional aspect, the SYNC sequence is the same for both the first operating frequency band and the second operating frequency band. In another optional aspect, the SYNC sequence includes at least one initial OFF period, at least one Manchester encoded portion and at least one non-Manchester encoded portion. In a further optional aspect, a duration of the AMP preamble is the same for both the first data rate and the second data rate.

To implement various operations described herein, computer program code (i.e., program instructions for carrying out these operations) may be written in any combination of one or more programming languages, including an object-oriented programming language such as Java, Smalltalk, Python, C++, or the like, conventional procedural programming languages, such as the “C” programming language or similar programming languages, or any of machine learning software. These program instructions may also be stored in a computer readable storage medium that can direct a computer system, other programmable data processing apparatus, controller, or other device to operate in a particular manner, such that the instructions stored in the computer readable medium produce an article of manufacture including instructions which implement the operations specified in the block diagram block or blocks. The program instructions may also be loaded onto a processing core, processing circuitry, computer, other programmable data processing apparatus, controller, or other device to cause a series of operations to be performed on the computer, or other programmable apparatus or devices, to produce a computer implemented process such that the instructions upon execution provide processes for implementing the operations specified in the block diagram block or blocks.

As may be used herein, the term(s) “configured to”, “operably coupled to”, “coupled to”, and/or “coupling” includes direct coupling between items and/or indirect coupling between items via an intervening item (e.g., an item includes, but is not limited to, a component, an element, a circuit, and/or a module) where, for an example of indirect coupling, the intervening item does not modify the information of a signal but may adjust its current level, voltage level, and/or power level. As may further be used herein, inferred coupling (i.e., where one element is coupled to another element by inference) includes direct and indirect coupling between two items in the same manner as “coupled to”.

As may further be used herein, the term(s) “arranged to”, “configured to”, “operable to”, “coupled to”, or “operably coupled to” indicates that an item includes one or more of power connections, input(s), output(s), etc., to perform, when activated, one or more its corresponding functions and may further include inferred coupling to one or more other items. As may still further be used herein, the term “associated with” includes direct and/or indirect coupling of separate items and/or one item being embedded within another item.

As may be used herein, one or more claims may include, in a specific form of this generic form, the phrase “at least one of a, b, and c” or of this generic form “at least one of a, b, or c”, with more or less elements than “a”, “b”, and “c”. In either phrasing, the phrases are to be interpreted identically. In particular, “at least one of a, b, and c” is equivalent to “at least one of a, b, or c” and shall mean a, b, and/or c. As an example, it means: “a” only, “b” only, “c” only, “a” and “b”, “a” and “c”, “b” and “c”, and/or “a”, “b”, and “c”.

As may also be used herein, the terms “processor”, “processing circuitry”, “processing circuit”, “processing module”, and/or “processing unit” may be a single processing device or a plurality of processing devices. Such a processing device may be a microprocessor, microcontroller, digital signal processor, microcomputer, central processing unit, field programmable gate array, programmable logic device, state machine, logic circuitry, analog circuitry, digital circuitry, and/or any device that manipulates signals (analog and/or digital) based on hard coding of the circuitry and/or operational instructions. Further, such a processing device may include a plurality of processing cores or processing domains, which may operate on separate power domains. The processor, processing circuitry, processing circuit, processing module, and/or processing unit may be (or may further include) memory and/or an integrated memory element, which may be a single memory device, a plurality of memory devices, and/or embedded circuitry of another processor, processing circuitry, processing circuit, processing module, and/or processing unit. Such a memory device may be a read-only memory, random access memory, volatile memory, non-volatile memory, static memory, dynamic memory, flash memory, cache memory, and/or any device that stores digital information. Note that if the processor, processing circuitry, processing circuit, processing module, and/or processing unit includes more than one processing device, the processing devices may be centrally located (e.g., directly coupled together via a wired and/or wireless bus structure) or may be distributedly located (e.g., cloud computing via indirect coupling via a local area network and/or a wide area network). Further note that if the processor, processing circuitry, processing circuit, processing module, and/or processing unit implements one or more of its functions via a state machine, analog circuitry, digital circuitry, and/or logic circuitry, the memory and/or memory element storing the corresponding operational instructions may be embedded within, or external to, the circuitry comprising the state machine, analog circuitry, digital circuitry, and/or logic circuitry. Still further note that, the memory element may store, and the processor, processing circuitry, processing circuit, processing module, and/or processing unit executes, hard coded and/or operational instructions corresponding to at least some of the steps and/or functions illustrated in one or more of the figures. Such a memory device or memory element can be included in an article of manufacture.

One or more embodiments have been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claims.

To the extent used, the logic diagram block boundaries and sequence could have been defined otherwise and still perform the certain significant functionality. Such alternate definitions of both functional building blocks and logic diagram blocks and sequences are thus within the scope and spirit of the claims. One of average skill in the art will also recognize that the functional building blocks, and other illustrative blocks, modules and components herein, can be implemented as illustrated or by discrete components, application specific integrated circuits, processors/processing cores executing appropriate software and the like or any combination thereof.

The one or more embodiments are used herein to illustrate one or more aspects, one or more features, one or more concepts, and/or one or more examples. A physical embodiment of an apparatus, an article of manufacture, a machine, and/or of a process may include one or more of the aspects, features, concepts, examples, etc. described with reference to one or more of the embodiments discussed herein. Further, from figure to figure, the embodiments may incorporate the same or similarly named functions, steps, modules, etc. that may use the same or different reference numbers and, as such, the functions, steps, modules, etc. may be the same or similar functions, steps, modules, etc. or different ones.

The term “module” may be used in the description of one or more of the embodiments. A module implements one or more functions via a device such as a processor or other processing device or other hardware that may include or operate in association with a memory that stores operational instructions. A module may operate independently and/or in conjunction with software and/or firmware. As also used herein, a module may contain one or more sub-modules, each of which may be one or more modules.

As may further be used herein, a computer readable memory includes one or more memory elements. A memory element may be a separate memory device, multiple memory devices, or a set of memory locations within a memory device. Such a memory device may be a read-only memory, random access memory, volatile memory, non-volatile memory, static memory, dynamic memory, flash memory, cache memory, a quantum register or other quantum memory and/or any other device that stores data in a non-transitory manner. Furthermore, the memory device may be in a form of a solid-state memory, a hard drive memory or other disk storage, cloud memory, thumb drive, server memory, computing device memory, and/or other non-transitory medium for storing data. The storage of data includes temporary storage (i.e., data is lost when power is removed from the memory element) and/or persistent storage (i.e., data is retained when power is removed from the memory element). As used herein, a transitory medium shall mean one or more of: (a) a wired or wireless medium for the transportation of data as a signal from one computing device to another computing device for temporary storage or persistent storage; (b) a wired or wireless medium for the transportation of data as a signal within a computing device from one element of the computing device to another element of the computing device for temporary storage or persistent storage; (c) a wired or wireless medium for the transportation of data as a signal from one computing device to another computing device for processing the data by the other computing device; and (d) a wired or wireless medium for the transportation of data as a signal within a computing device from one element of the computing device to another element of the computing device for processing the data by the other element of the computing device. As may be used herein, a non-transitory computer readable memory is substantially equivalent to a computer readable memory. A non-transitory computer readable memory can also be referred to as a non-transitory computer readable storage medium.

While particular combinations of various functions and features of the one or more embodiments have been expressly described herein, other combinations of these features and functions are likewise possible. The present disclosure is not limited by the particular examples disclosed herein and expressly incorporates these other combinations.

What is claimed is:

1. A method for communicating with an ambient power (AMP) tag device by an AMP-compliant WiFi device, the method comprising:
generating a physical layer protocol data unit (PPDU), the PPDU including:
a preamble, wherein the preamble is compliant with an Institute of Electrical and Electronics Engineers (IEEE) 802.11 standard;
an AMP preamble including a synchronization (SYNC) field; and
an AMP data frame carrying downlink (DL) data, wherein the SYNC field of the AMP preamble includes an On-Off keying (OOK) modulated SYNC sequence, the SYNC sequence including an indication of a first data rate or a second data rate for the DL data or an indication of a first operating frequency band or a second operating frequency band; and
transmitting, by the WiFi device, the PPDU for reception by the AMP tag device.

2. The method of claim 1, wherein the SYNC sequence is different for backscattering operation and non-backscattering operation.

3. The method of claim 1, wherein the SYNC sequence is for backscattering operation and includes an initial OFF portion, at least one non-Manchester encoded code violation portion, and at least one Manchester encoded portion.

4. The method of claim 3, wherein the initial OFF portion has a first duration to indicate the first operating frequency band and a second duration to indicate a second operating frequency band.

5. The method of claim 1, wherein the SYNC sequence is for backscattering operation and the SYNC field has the same OOK sequence for both the first operating frequency band and the second operating frequency band.

6. The method of claim 1, wherein the SYNC sequence is for non-backscattering operation and a duration of the SYNC field is the same for both the first data rate and the second data rate.

7. The method of claim 1, wherein the SYNC sequence includes a basic sequence S to indicate the first data rate and a complementary sequence S to indicate the second data rate.

8. The method of claim 1, wherein the SYNC sequence includes a basic sequence S to indicate the first data rate and a sequence [S̅, S̅] to indicate the second data rate.

9. The method of claim 1, wherein the first data rate is 250 Kilobits per second (Kbps) and the second data rate is 1 Megabits per second (Mbps).

10. The method of claim 1, wherein the AMP preamble is for non-backscattering operation and further includes an end of SYNC portion.

11. The method of claim 1, wherein the SYNC sequence has a pulse width (PW) duration of 2 microseconds (us) for a 2.4 GHz operating frequency band.

12. The method of claim 1, wherein the SYNC sequence has a pulse width (PW) duration of 8 microseconds (us) for a sub-1 GHz operating frequence band.

13. The method of claim 1, wherein the SYNC sequence further includes at least four consecutive “ON” pulses.

14. The method of claim 1, wherein the SYNC sequence is formed of pulses having a first pulse width to indicate a first data rate and a second pulse width to indicate a second data rate.

15. The method of claim 1, wherein the SYNC sequence includes a first ON portion having a first duration and a second ON portion having a second duration, and wherein the ratio of the first duration and the second duration is greater than 3:1.

16. The method of claim 1, wherein the SYNC sequence is [0 1 1 1 1 0 1 0].

17. The method of claim 1, wherein the PPDU further includes a backscattering segment, the backscattering segment including a carrier waveform configured to provide power to an AMP tag device to backscatter information to the AMP-compliant WiFi device.

18. The method of claim 1, wherein the AMP preamble and AMP data frame are compliant with an IEEE 802.11 bp amendment to the IEEE 802.11 standard.

19. A method for communicating with an ambient power (AMP) tag device by an AMP-compliant WiFi device, the method comprising:
generating a physical layer protocol data unit (PPDU), the PPDU including:
a preamble, wherein the preamble is compliant with an Institute of Electrical and Electronics Engineers (IEEE) 802.11 standard;
an AMP preamble including a synchronization (SYNC) field;
an AMP data frame carrying downlink (DL) data, wherein the SYNC field of the AMP preamble includes an On-Off keying (OOK) modulated SYNC sequence, the SYNC sequence including an indication of a first operating frequency band or a second operating frequency band; and
a backscattering segment including a carrier waveform comprised of a sequence of single carrier symbols; and
transmitting, by the WiFi device, the PPDU for reception by the AMP tag device.

20. The method of claim 19, wherein the carrier waveform comprises a repeated base waveform.

21. The method of claim 19, wherein the SYNC sequence includes at least one Manchester encoded portion and at least one non-Manchester encoded portion.

22. The method of claim 19, wherein the SYNC sequence includes at least one code violation subfield.

23. The method of claim 19, wherein the AMP preamble and AMP data frame are compliant with an IEEE 802.11 bp amendment to the IEEE 802.11 standard.

24. An ambient power (AMP)-compliant WiFi device, comprising:
one or more wireless transceivers; and
one or more processors operably coupled to the one or more wireless transceivers, wherein the one or more processors are arranged to:
generate a physical layer protocol data unit (PPDU), the PPDU including:
a preamble, wherein the preamble is compliant with an Institute of Electrical and Electronics Engineers (IEEE) 802.11 standard;
an AMP preamble including a synchronization (SYNC) field; and
an AMP data frame carrying downlink (DL) data, wherein the SYNC field of the AMP preamble includes an On-Off keying (OOK) modulated SYNC sequence, the SYNC sequence including an indication of a first data rate or a second data rate for the DL data or an indication of a first operating frequency band or a second operating frequency band; and
transmit, via the one or more wireless transceivers, the PPDU for reception by an AMP tag device.

25. The AMP-compliant WiFi device of claim 24, wherein the PPDU further includes a backscattering segment, the backscattering segment including a carrier waveform having a repeated base waveform.

26. The AMP-compliant WiFi device of claim 24, wherein the SYNC sequence is the same for both the first operating frequency band and the second operating frequency band.

27. The AMP-compliant WiFi device of claim 24, wherein the SYNC sequence includes at least one initial OFF period, at least one Manchester encoded portion and at least one non-Manchester encoded portion.

28. The AMP-compliant WiFi device of claim 24, wherein a duration of the AMP preamble is the same for both the first data rate and the second data rate.
